(19) United States
(12) Patent Application Publication
(10) Pub. No.: US 2017/0141309 A1
(43) Pub. Date: May 18, 2017

(54) THIN FILM FABRICATING DEVICE AND METHOD FOR MANUFACTURING ORGANIC LIGHT EMITTING DEVICE USING THE SAME

(71) Applicant: SAMSUNG ELECTRONICS CO., LTD., Suwon-si (KR)

(72) Inventors: Nobuo HAMAMOTO, Suwon-si (KR); Hiroshi MIYAZAKI, Hwaseong-si (KR)

(21) Appl. No.: 15/140,553

(22) Filed: Apr. 28, 2016

(30) Foreign Application Priority Data
Nov. 13, 2015 (KR) 10-2015-0159920

(51) Int. Cl. H01L 51/00; B05B 5/16; B05B 5/03; B05B 5/053; B05B 5/025

(52) U.S. Cl. CPC H01L 51/0003; B05B 5/0533; B05B 5/0255; B05B 5/032; B05B 5/16; B05B 5/0536

(57) ABSTRACT

A thin-film forming device includes a plurality of electrodes for spraying a thin-film forming material; and a substrate stand disposed to face the plurality of pipe electrodes and which holds a substrate for forming a thin film thereon, where a gas spraying channel for spraying gas for drying the sprayed thin-film forming material is defined in each of the electrodes, and when a gap among neighboring electrodes is denoted by L and a shortest distance to the held substrate from the electrodes is denoted by Z, L and Z satisfy the following inequation Z≧5L.

### RELATED APPLICATIONS

This application claims priority to Korean Patent Application No. 10-2015-0159920, filed on Nov. 13, 2015, and all the benefits accruing therefrom under 35 U.S.C. §119, the content of which in its entirety is herein incorporated by reference.

### BACKGROUND

1. Field

The disclosure relates to a thin-film forming device and a method for manufacturing an organic light-emitting diode using the thin-film forming device.

2. Description of the Related Art

An organic electro-luminescence (“EL”) diode is a current driven light-emitting device for installing electrodes on respective sides of a thin film of an organic material, applying a voltage between the electrodes, and using emission of light generated by a recombination of electrons and holes injected into an organic thin film on the respective sides of the electrode. Since the EL diode is a self-emissive device having high light-emission luminance with a low voltage and having great visibility, various kinds of application studies on light and slim displays or lighting have been actively progressed.

Methods for manufacturing an organic thin film generally used for manufacturing the organic EL diode include a dry process, e.g., a vacuum deposition method, and a wet process, e.g., a spin court method. The dry process is a process for manufacturing a film using a relatively low molecular organic material. In the dry process, it may be easy to control the thickness, coated areas may be divided by using a mask with holes of proper sizes, and it may be easy to manufacture a structure for stacking organic materials with different properties. Particularly, a light emission efficiency of the organic EL diode and a lifespan of the organic EL diode may be substantially increased through a multi-layering technique for easily manufacturing a stacked structure, and the organic EL diode has been used to a number of applications as a practicable display. However, such a multi-layering technique typically uses a vacuum device, the cost for initial adoption and maintenance of which is substantially high. Furthermore, it may be difficult to use such a vacuum device for multi-layering on a large substrate, and it may be resultantly limited to improve productivity or to reduce the manufacturing cost.

The wet process is applicable to polymer materials with high physical stability such as film manufacturing or heat resistance, a simple device may be used for such a wet process, and such a wet process may be performed without being under a specific condition such as vacuum so such a wet process may be considered to be suitable for mass production and appropriate for manufacturing low-price products. However, it is an important factor to manufacture a stacked structure using materials with different properties to realize the high efficiency and long lifespan, but the wet process has a problem that a solvent of an upper-layered thin-film forming material melts into a lower-layered organic material to strip off the lower layer, which is desired to be prevented. Additives such as a crosslinking hardener may be used to prevent such a problem, but the additives are known to deteriorate a light emission function, so it is very much difficult to realize a multi-layered structure with high performance that does not damage the function of the diode.

Many proposals for using an electro-spray (“ES”) method to the manufacturing of organic EL diodes with a feature that it may easily manufacture a pattern have been submitted. The ES method represents a method for spraying a solution of a functional material and attaching the solution to the substrate by applying a high voltage between a conductive substrate and a nozzle for discharging the solution. Such a method may be effectively used to stack multiple layers since the charged solution changes into fine nano-order level liquid droplets to resist against each other, be distributed, and form minute nano-order level liquid droplets, the solvent vaporizes according to a steep increase of a surface area, and the almost dried organic material in the solution is attached to the substrate to generate a uniform layer.

The above information disclosed in this Background section is only for enhancement of understanding of the background of the described technology and therefore it may contain information that does not form the prior art that is already known in this country to a person of ordinary skill in the art.

### SUMMARY

The described technology has been made in an effort to provide a thin-film forming device applicable to mass production and forming a uniform nano-order layer in a stable manner, and a method for manufacturing an organic light-emitting diode using the thin-film forming device.

An exemplary embodiment of a thin-film forming device includes a plurality of electrodes for spraying a thin-film forming material; and a substrate stand disposed to face the plurality of pipe electrodes and which holds a substrate for forming a thin film thereon, where the a gas spraying channel for spraying gas for drying the sprayed thin-film forming material is defined in each of the electrodes, and when a gap among neighboring electrodes is denoted by L and a shortest distance to the held substrate from the electrodes is denoted by Z, L and Z satisfy the following inequation: Z≧5L.

In an exemplary embodiment, L may have a value in a range of about 5 millimeters (mm) to about 20 mm.

In an exemplary embodiment, Z may have a value equal to or greater than about 30 mm.

In an exemplary embodiment, when a thickness deviation of the thin film is denoted by δ (%), δ may satisfy the following equation:

$$δ = 40840 * {e}^{- 1.96 * \frac{Z}{L}} ,$$

and Z and L may be satisfied that Z≧5.06L.

In an exemplary embodiment, the gas spraying channel may spray a gas including at least one selected from nitrogen (N₂), argon (Ar), helium (He), neon (Ne), xenon (Xe), and krypton (Kr).

In an exemplary embodiment, the gas spraying channel may extend along a center axis of the electrode.

In an exemplary embodiment, the electrode may be in a pipe shape, and a transverse cross-section of the gas channel may have a circular shape.

In an exemplary embodiment, a front end of the electrode may have a cylindrical shape, and a transverse cross-section of the gas channel may have a circular shape.

In an exemplary embodiment, the thin-film forming device may further include a plated layer disposed on a surface of the electrode.

In an exemplary embodiment, the plated layer may include at least one selected from a stainless steel, tungsten, gold, and platinum.

In an exemplary embodiment, the thin-film forming device may further include an electrode tank which contains the thin-film forming material, where at least part of the electrode may be disposed in the electrode tank.

In an exemplary embodiment, when the thin-film forming material is contained in the electrode tank, the electrode may be higher than the thin-film forming material by about 0.15 mm to about 4 mm.

In an exemplary embodiment, the substrate stand may be disposed below the electrodes.

According to another embodiment of the invention, a method for manufacturing an organic light-emitting diode includes forming an organic layer using the thin-film forming device described above.

### BRIEF DESCRIPTION OF THE DRAWINGS

These and/or other features of the invention will become apparent and more readily appreciated from the following detailed description of embodiments thereof, taken in conjunction with the accompanying drawings, in which:

FIG. 1 shows a schematic diagram of a thin-film forming device according to an exemplary embodiment;

FIG. 2 shows a cross-sectional view of an electrode of a thin-film forming device according to an exemplary embodiment;

FIG. 3 is a cross-sectional view of an electrode of FIG. 2 with respect to a plane that is vertical to a center axis;

FIG. 4 is an enlarged view showing an end portion of an electrode of FIG. 2;

FIG. 5 is a schematic view showing velocity profiles for respective positions of gas sprayed by a gas spraying channel;

FIG. 6 is a graph for indicating a velocity rate with respect to a distance from a center axis of gas sprayed by a gas spraying channel in a thin-film forming device according to an exemplary embodiment;

FIG. 7 is a graph for indicating a form of a thin film provided according to a shortest distance to a substrate from a plurality of electrodes in a thin-film forming device according to an exemplary embodiment;

FIG. 8 is a graph for indicating a total velocity distribution according to a distance from a center axis of gas sprayed by a gas spraying channel when L=10 millimeters (mm) and Z=20 mm in a thin-film forming device according to an exemplary embodiment;

FIGS. 9A and 9B are graphs for indicating a total velocity distribution according to a distance from a center axis of gas sprayed by a gas spraying channel in a thin-film forming device according to an exemplary embodiment where FIG. 9A is a graph when L=10 mm and Z=50 mm and FIG. 9B is a magnified graph of FIG. 9A in a y-axis direction;

FIGS. 10A and 10B are graphs for indicating a total velocity distribution according to a distance from a center axis of gas sprayed by a gas spraying channel in a thin-film forming device according to an exemplary embodiment where FIG. 10A is a graph when L=10 mm and Z=100 mm and FIG. 10B is a magnified graph of FIG. 10A in a y-axis direction;

FIG. 11 is a graph for indicating a total velocity distribution according to a distance from a center axis of gas sprayed by a gas spraying channel when L=2 mm and Z=5 mm in a thin-film forming device according to an exemplary embodiment;

FIGS. 12A and 12B are graphs for indicating a total velocity distribution according to a distance from a center axis of gas sprayed by a gas spraying channel in a thin-film forming device according to an exemplary embodiment where FIG. 12A is a graph when L=2 mm and Z=10 mm and FIG. 12B is a magnified graph of FIG. 12A in a y-axis direction;

FIGS. 13A and 13B shows a graph for indicating a total velocity distribution according to a distance from a center axis of gas sprayed by a gas spraying channel in a thin-film forming device according to an exemplary embodiment where FIG. 13A is a graph when L=2 mm and Z=15 mm and FIG. 13B is a magnified graph of FIG. 13A in a y-axis direction;

FIG. 14 is a graph for indicating a relationship of δ with respect to Z according to a change of L;

FIG. 15 is a graph for indicating a correlation of L and B expressed in Table 1,

FIG. 16 is a schematic diagram showing a thin-film forming device according to an alternative exemplary embodiment; and

FIG. 17 is an enlarged view showing an end portion of an electrode of FIG. 16.

### DETAILED DESCRIPTION

The embodiments will be described more fully hereinafter, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Further, in the specification, the word “on” means positioning on or below the object portion, but does not essentially mean positioning on the upper side of the object portion based on a gravity direction.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

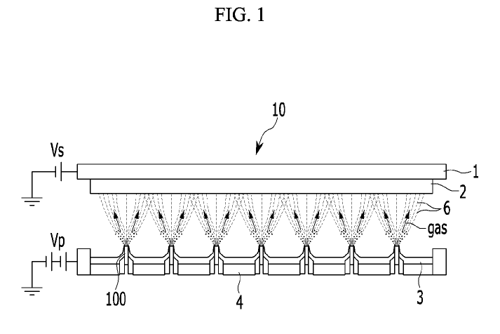

A schematic structure of a thin-film forming device 10 according to an exemplary embodiment will now be described with reference to FIG. 1.

FIG. 1 shows a schematic diagram of a thin-film forming device according to an exemplary embodiment.

An exemplary embodiment of the thin-film forming device includes a substrate stand 1 for receiving a substrate 2; and an electrode tank 4 disposed to face the substrate stand 1, in which a plurality of electrodes 100 are disposed in a predetermined arrangement, and which receives a thin-film forming material.

The substrate stand 1 is a device for disposing the substrate 2 on which a thin film will be provided or formed on a position facing the electrode 100, and substrate stand 1 may be disposed to face the electrode 100 as shown in FIG. 1 by installing the substrate 2 with a fixing device (not shown) such as an aspirator, and providing the installed substrate 2 in a thin film forming area.

In an exemplary embodiment, as shown in FIG. 1, the substrate stand 1 may dispose the substrate 2 to be on the electrode 100 so that the thin-film forming material 3 may be provided toward a surface of the substrate 2 (which is called an up-flow type thin film formation), but the positions of the substrate 2 and the electrode 100 are not restricted thereto, and the positions of the substrate stand 1 and the substrate 2 provided thereon may be set in various ways to allow the electrode 100 to be disposed to face the substrate 2.

The electrode tank 4 may include a plurality of electrodes 100 arranged in a predetermined arrangement such as a matrix form, and a wall may be provided therearound such that a liquid thin-film forming material 3 may be filled therein with a predetermined height. A water level controller (not shown) may be installed in the electrode tank 4 to control the water level of the thin-film forming material 3 to be constant.

The electrodes 100 may be disposed at regular intervals in the electrode tank 4, and the electrodes 100 may have various shapes such as sharp and pointed to generate a Taylor cone. The intervals of the electrodes 100 may not be regular and may be changed into a predetermined pattern. The electrode tank 4 may include or be made of a conductor to apply a potential to the electrode 100, or a portion thereof contacting the electrode 100 may include be made of a conductor.

When a predetermined voltage (Vp) is applied to the electrode 100, the thin-film forming material 3 is gathered at an end portion of the electrode 100 facing the substrate 2, and the thin-film forming material 3 is sprayed as fine liquid droplets 5 from the electrode 100 by an electric field generated by the electrodes 100. The sprayed liquid droplets 5 may be disposed (e.g., attached or stored) on a surface of the substrate 2 to form a thin film.

In an exemplary embodiment, the voltage applied to the electrode 100 may be in a range of about 3 kilovolts (kV) to about 50 kV, in a range of about 3 kV to about 30 kV, or in a range of about 5 kV to about 25 kV, for example, but not being limited thereto.

The thin-film forming devices 10 may be connected to each other in series, and the electrodes 100 of the thin-film devices 10 may be connected to each other to be disposed in a plurality of directions. In an exemplary embodiment, a plurality of ring electrodes (not shown) in a net form, a grid electrode (not shown) or a lens electrode (not shown) may be disposed between the electrode 100 and the substrate 2. In such an embodiment, where a plurality of ring electrodes (not shown), the lens electrode or the grid electrode (not shown) is further disposed between the electrode 100 and the substrate 2, the electric field generated in the thin-film forming device 10 may be controlled in various ways and a progressing direction of the sprayed liquid droplets 5 may be diversified.

As described above, the thin-film forming device 10 is a device for applying a predetermined voltage (Vp) to the electrode 100 to generate an electric field between the electrode 100 and the substrate 2, and progressing the thin-film forming material 3 in the form of liquid droplets 5 (which is referred to as an electrostatic deposition (“ESD”) device using a thin film formation according to an electro-spraying method), and a detailed operation of the thin-film forming device 10 will be described later in detail.

In an exemplary embodiment, as shown in FIG. 1, the electrode 100 may spray gas, as well as to the thin-film forming material 3, in a directed indicated by arrows. The sprayed gas is sprayed to the liquid droplets 5 sprayed by the end portion of the electrode 100 to dry moisture or solvents in the liquid droplets 5 and guide the sprayed direction toward the substrate 2. The gas sprayed by the electrode 100 and detailed effects thereof will be described later in detail.

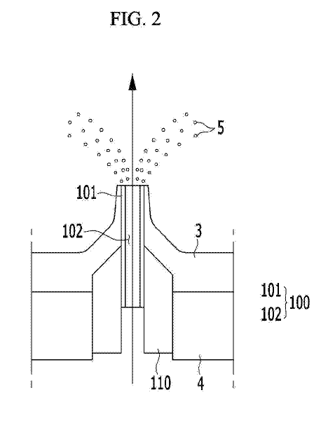

An electrode 100 of a thin-film forming device according to an exemplary embodiment will now be described in detail with reference to FIG. 2 to FIG. 4.

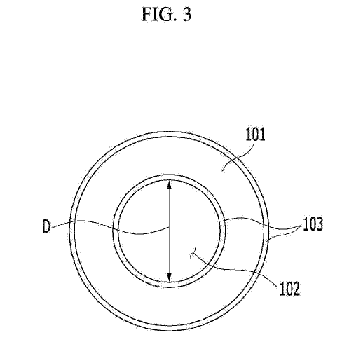

FIG. 2 shows a cross-sectional view of an electrode of a thin-film forming device according to an exemplary embodiment, and FIG. 3 is a cross-sectional view of an electrode of FIG. 2 with respect to a plane that is vertical to a center axis.

In an exemplary embodiment of the thin-film forming device 10, the electrode 100 may have a bar, needle, or pipe-type structure with a diameter of several to several hundreds of micrometers. A plurality of insertion holes are defined or formed in the electrode tank 4 with a predetermined arrangement to receive the electrode 100. A plurality of electrodes 100 may be inserted into the insertion holes and may be fixed to the electrode tank 4.

When the size of the electrode 100 is relatively small, that is, several to several tens of micrometers or the electrodes 100 with different sizes are to be used, a receiving member 110 to be inserted into the insertion hole and fixed thereto may be used as shown in FIG. 2. The receiving member 110 includes a receiving hole for providing a space in which the electrode 100 will be received.

In a like manner of the electrode tank 4, the receiving member 110 may include or be made of conductor or a portion thereof contacting at least one of the electrode tank 4 and the electrode 100 may include or be made of conductor.

In an exemplary embodiment, the insertion holes 41 with a single size are formed in the electrode tank 4 and the receiving member 110 may be inserted into the insertion holes 41, such that the electrodes 100 with a relatively small size or various sizes are attachable/detachable. Accordingly, in such an embodiment, the thin film forming condition may be controlled in various ways depending on the processes for forming a thin film.

Referring to FIG. 2, in an exemplary embodiment, the electrode 100 is a structure extending along the center axis passing through a center of the electrode 100, and as shown in FIG. 3, the transverse cross-sectional shape incised with respect to the plane that is vertical to the center axis is a circular arc so the electrode 100 may have a circular pipe shape. However, the exemplary embodiment is not restricted to the above-described shape.

The electrode 100 may have a single pipe shape including a body 101 and a gas spraying channel 102 that is a path extending along the center axis of the body 101 is defined by the body 101.

The body 101 may include or be made of a conductor such as a stainless steel, tungsten or platinum, and may have conductivity by forming a conductor plated layer on an insulator such as glass. The body 101 may be a micro tube with a thickness of several to several tens of micrometers, and including nickel, for example, or the body 101 may have a structure in which a plated layer is disposed on a micro tube.

Referring to FIG. 3, a plated layer 103 may be provided on a surface of the body 101. The plated layer 103 may be a metal layer including at least one selected from a stainless steel, tungsten, gold, and platinum. The plated layer 103 may be disposed or coated on an external circumferential surface of the body 101 and on an interior circumference of the body 101 where the gas spraying channel 102 is provided. Accordingly, conductivity of the body 101 may be strengthened, and damage to the interior circumference of the body 101 that may occur when the gas is continuously sprayed may be prevented.

In an exemplary embodiment, a width D of the gas spraying channel may be in a range of about 10 micrometers (μm) to about 500 μm, in a range of about 10 μm to about 300 μm, or in a range of about 10 μm to about 250 μm, for example, so that the sprayed gas may be fluently supplied and the size of the entire electrode 100 may not be increased.

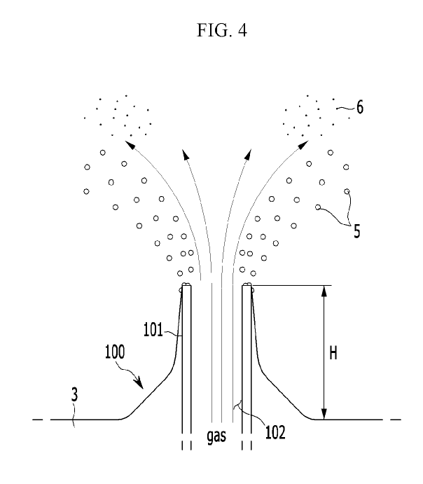

FIG. 4 is an enlarged view showing an end portion of an electrode of FIG. 2.

From among the respective end portions of the electrode 100, the end portion of the electrode 100 of FIG. 4, that is, the end portion where the liquid droplets 5 and sprayed gas are sprayed, will be defined as a front end, for ease of description.

The front end of the electrode 100 may have a flat circular pipe shape as shown in FIG. 4, but not being limited thereto, and the front end of the electrode 100 may be formed to be a cone or pyramid from which an end is incised (not an acute type), a cylinder or prism, a hemisphere or semi-oval, or a shape (caldera type) like a ball or cone from which a center is dug in a hemispherical and concave manner.

Referring to FIG. 4, the thin-film forming material 3 is gathered at the front end of the electrode 100 and is then sprayed in a form of liquid droplets 5. The front end of the electrode 100 has a cylindrical shape in an exemplary embodiment so the thin-film forming material 3 is gathered at the circular cross-section of the electrode 100 and is sprayed toward the substrate in a radial direction with reference to FIG. 4.

The electrode 100 may be higher than the thin-film forming material 3 in the electrode tank 4 by a predetermined value. In one exemplary embodiment, for example, a height difference (H) between the electrode 100 and the thin-film forming material 3 may be in a range of about 0.15 millimeters (mm) to about 4 mm or in a range of about 0.8 mm to about 1.5 mm.

In such an embodiment, where the front end of the electrode 100 is provided to be higher than a liquid surface of the thin-film forming material 3 by about 0.15 mm to about 4 mm, a function for forming a thin film may be further efficiently realized. This is because the sprayed liquid droplets 5 are sprayed by forming a Taylor cone by the electric field focused on the front end of the electrode 100 when the thin-film forming material 3 provided below the electrode 100 rises to the front end of the electrode 100.

In such an embodiment, it is desirable for the front end of the electrode 100 to be higher than the thin-film forming material 3 to generate a concentration of electric field, and when the front end of the electrode 100 is provided to be too high, the thin-film forming material 3 may not sufficiently increase. Therefore, in such an embodiment, the height of the front end of the electrode 100 is controlled to be within the above-described range such that the liquid surface of the thin-film forming material 3 may effectively increase and the electric field may be effectively concentrated.

The gas spray channel 102 is connected to a gas supplier (not shown) to spray gas to the substrate from the front end of the electrode 100. In an exemplary embodiment, the sprayed gas may include inert gas or highly stable gas without reactivity to the liquid droplets 5. In one exemplary embodiment, for example, the sprayed gas may be inert gas such as highly concentrated nitrogen (N₂) gas or highly concentrated argon (Ar) gas occupying more than about 90% of the entire volume, neon (Ne) gas, helium (He) gas, xenon (Xe) gas, or krypton (Kr) gas, a mixed gas thereof, or air including nitrogen (N₂) gas occupying about 78% of the entire volume and argon (Ar) gas occupying about 1% of the entire volume.

A temperature of the sprayed gas when being sprayed from the front end of the electrode 100 may be greater than a temperature of the liquid droplets 5 when being sprayed from the front end of the electrode 100. In general, the liquid droplets 5 sprayed from the front end of the electrode 100 may have various sizes depending on a voltage applied to the electrode 100, and when the liquid droplets 5 include a large amount of solvents or moisture, the liquid droplets 5 may be sprayed as a relatively big size so the sizes of the sprayed liquid droplets 5 may not be uniform when a same voltage is applied.

In an exemplary embodiment, where the temperature of the sprayed gas at a spraying time is set to be higher than that of the liquid droplets 5 at a spraying time as described above, the sprayed gas efficiently vaporizes and removes the moisture or solvent remaining in the liquid droplets 5 sprayed from the front end of the electrode 100 resultantly maintaining the uniform size of the sprayed liquid droplets 5.

Accordingly, in such an embodiment, uniformity of the thickness of the formed thin film may be improved. When such an embodiment is used for forming a thin film of an organic light emission diode, the light emission performance thereof may be improved by removing the solvent or moisture inside the material. That is, according to an exemplary embodiment, the thin-film forming device 10 for forming a quality-improved thin film is provided.

A detailed operation of the thin-film forming device 10 will now be described.

In an exemplary embodiment, the thin-film forming device 10 is an electrostatic deposition (“ESD”) device using Rayleigh instability. Rayleigh instability indicates a phenomenon in which, when the liquid surface is charged, the electrostatic repulsion caused by surface charges hinders reduction of a liquid surface by a surface tension. It represents a phenomenon that when the repulsion generated by the charged surface charges becomes greater than the surface tension, the liquid is divided to discharge very small liquid droplets with charges. Further, the ESD represents a thin coating technique for applying a high voltage to a tip of the needle to discharge very small liquid droplets and store them on a target substrate.

When a high voltage is applied to a cylindrical needle, the Rayleigh instability occurs at the tip of the needle. That is, when the charges, which are generated by the high voltage, remain on the surface and have an electrostatic repulsion that is stronger than the surface tension forming curvature of the liquid at the tip of the needle, the convex surface of the liquid changes to be concave at the tip of the needle. As a result, the concave tip becomes a cone called a

Taylor cone, and very small liquid droplets come out of the peak point of the Taylor cone, which is referred to as electro-spraying. The liquid droplets discharged in the above-described manner may be sprayed with the size of about 1 μm to about 7 μm when an appropriate condition and measuring method are used.

The liquid droplets sprayed with the size of micrometers are quickly dried because the specific surface of the sprayed liquid droplets area is very big. Therefore, the surface area of the liquid droplets is reduced, while maintaining the charges, through drying, and when the drying is progressed, a charge density increases and the electrostatic repulsion increases to repeat atomization. However, when the size of the sprayed liquid droplets becomes to be less than 1 μm, the sprayed liquid droplets lose the charges because of a corona discharge caused by a strong electric field generated by surface charges and no further fission. When the liquid droplets include a solid, the liquid droplets are vaporized to become solid particulates.

A process for generating a layer by attaching the particulates on a side such as a substrate and piling the layer is referred to as an ESD. A thin film of nano unit may be formed by using the ESD, which may be effectively used for a method for coating a low molecular material for manufacturing an organic light-emitting diode. In the ESD, the liquid is volatilized when the liquid droplets are piled. Accordingly, when a plurality of layers is provided with liquids of different compositions through the ESD, the layers may be formed with the phenomenon of permeation of liquid into a neighboring layer.

The electro-spray has various spraying forms by applying a high voltage.

In one exemplary embodiment, for example, a plurality of Taylor cones spray the liquid droplets starting from a single spray mode having a Taylor cone when the voltage is greater than a threshold applying voltage, passing through an oscillating-jet mode occurring when the voltage that is greater than the threshold applying voltage, undergoing a precession mode, and reaching a multi spray mode occurring when the voltage that is further greater than the threshold applying voltage.

The multi spray mode is appropriate for mass production when considering spray efficiency, but the multi spray mode may not be stably maintained since very high voltage is used for the multi spray mode. When the multi spray mode is not stably maintained, the spraying type may change to the oscillating-jet mode or the precession mode, uniform and small liquid droplets may not be sprayed in a secure manner but big and rough liquid droplets may be often generated, and the thickness of the generated thin film is resultantly non-uniform.

However, in an exemplary embodiment, a structure for applying a strong voltage to maintain the multi spray mode and for spraying gas to the outside from the inside of the electrode 100 using a single pipe type electrode 100 is provided. Accordingly, when the spraying type changes to the oscillating-jet mode or the precession mode, the size of the liquid droplets 5 may be controlled to be uniform by the sprayed gas.

The structure for spraying gas by using the single pipe type electrode 100 of the thin-film forming device 5 according to an exemplary embodiment may relatively uniformly maintain the size of the sprayed liquid droplets 5 with a very simple structure, compared to a conventional nozzle having a complicated structure such as a double-pipe type or a multiple-pipe type for concurrently supplying a thin-film forming material and gas, or a conventional complicated structure including a means for sending gas or dry gas in addition to an electrode for electro-spraying, thereby improving quality of the formed thin film and being suitable for mass production.

Regarding the thin-film forming device 10 according to an exemplary embodiment of FIG. 1, the voltage (Vp) applied to a plurality of electrodes 100 may maintain the multi spray mode, and the voltage (Vp) may be a relatively high voltage corresponding to an area for generating a corona discharge to the front end of the electrode 100. In one exemplary embodiment, for example, the voltage (Vp) may be in a range of about 3 kV to about 50 kV or in a range of about 5 kV to about 30 kV. When the voltage (Vp) applied to the electrode 100 is provided within the above-described range, part of moisture or solvents may be removed from the liquid droplets 5 gathered at the front end of the electrode 100 through the corona discharge and the liquid droplets 5 may be sprayed toward the substrate in a radial direction.

In one exemplary embodiment, for example, a spraying velocity of the gas sprayed from a plurality of electrodes 100 may be 1 to 100 times or 3 to 20 times the velocity of the liquid droplets 5 sprayed from the front end of the electrode 100, but not being limited thereto.

In such an embodiment, a wind velocity of the sprayed gas is controlled to be at least equal to or greater than the spraying velocity of the liquid droplets 5, so the sprayed gas may reach the sprayed liquid droplets 5 to vaporize the moisture or solvents remaining in the liquid droplets 5, and the liquid droplets 5 from which the moisture or solvents are vaporized may be dispersed as fine nano-order level solid sprayed particles 6.

A condition in which the solid sprayed particles 6 dispersed by the electrode 100 are uniformly distributed will now be described.

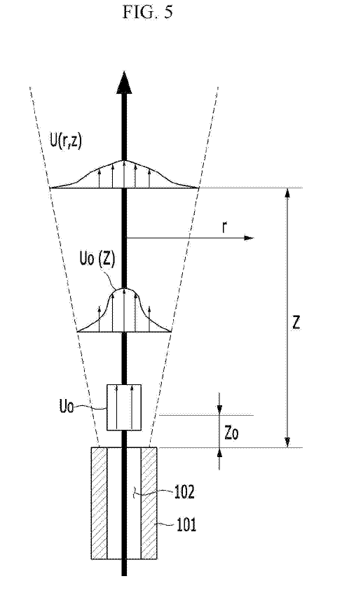

FIG. 5 is a schematic view showing velocity profiles for respective positions of gas sprayed by a gas spraying channel.

An axis extending in a vertical direction represents a center axis passing through the center of the electrode 100 in a vertical manner, Z indicates a distance from the front end of the electrode 100 in parallel to the center axis, and r indicates a distance from the center axis in a vertical direction to the center axis. Further, Uo, Uo(Z), and Uo(r,Z) represent velocities of the sprayed particles 6 at respective points separated in parallel to the center axis.

In the case when the sprayed gas is sprayed inside the single pipe type electrode 100 in the thin-film forming device 10 according to an exemplary embodiment, driving of the multi spray mode of the above-described liquid droplets 5 may be easily supplemented but the sprayed gas is continually sprayed into the thin-film forming device 10 with a velocity that is greater than a predetermined wind velocity through the gas spraying channel, a spray direction of the distributed solid sprayed particles 6 is induced by the sprayed gas, so a spraying distribution of the sprayed particles 6 inside the thin-film forming device 10 becomes different depending on the distance from the electrode 100.

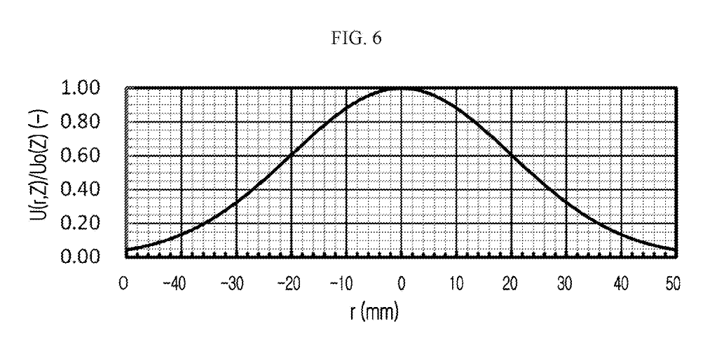

Referring to FIG. 6, up to the distance Z0 that is relatively near the electrode 100, the sprayed particles 6 influenced by the sprayed gas move straight at a regular velocity (hereinafter, an initial velocity) Uo according to a constant spraying velocity of the sprayed gas. That is, the sprayed particles 6 are directly sprayed at the initial velocity Uo by the sprayed gas, and a distance to a threshold point where the sprayed particles 6 are directly sprayed by the sprayed gas from the front end of the electrode 100 is referred to as a threshold distance (Zo).

The threshold distance (Zo) represents a distance within which a spraying force of the sprayed gas gives an influence, and in general, it may have the distance 8 to 10 times the width of the gas spraying channel.

However, when the sprayed particles 6 pass through the threshold distance (Zo), the influence by the sprayed gas gradually reduces. In this case, a center spray velocity (hereinafter, a center velocity) Uo(Z) that is the velocity of the particles sprayed along the center axis on the center axis from among the sprayed particles 6 is inversely proportional to Z. That is, the center velocity Uo(Z) represents the velocity of the sprayed particles 6 that are sprayed along the center axis when r=0.

Further, the electrode 100 sprays the sprayed particles 6 in the radial direction so the spraying velocity of the sprayed particles 6 passing through the threshold distance (Zo) and moving is influenced by r as well as Z. That is, a velocity profile of the sprayed particles 6 having passed through the threshold distance (Zo) is influenced by r and Z and it may be expressed with a same equation as U(r, Z).

FIG. 6 shows a graph for indicating a velocity rate with respect to a distance from a center axis of gas sprayed by a gas spraying channel in a thin-film forming device according to an exemplary embodiment.

In the graph of FIG. 6, y axis represents a value obtained by dividing the velocity profile U(r,Z) of the sprayed particles 6 having passed through the threshold distance (Zo) by the center velocity Uo(Z), where the center velocity Uo(Z) is the greatest, so it may be found how the velocity is distributed when it becomes distant from the center axis with respect to the center velocity Uo(Z).

That is, this is the case when the center velocity Uo(Z) is provided when r=0, that is, the case of the center velocity when the sprayed particles 6 move along the center axis has the quickest velocity, and when they become distant from the center axis, the velocity gradually reduces to show a form of a normal distribution in a like manner of the graph of FIG. 6.

The form of the graph of FIG. 6 corresponds to the form of the thin film to be generated on the substrate. That is, when the substrate is disposed to be separated from the electrode 100 by Z, the thin film corresponding to the graph of FIG. 6 is formed on the substrate.

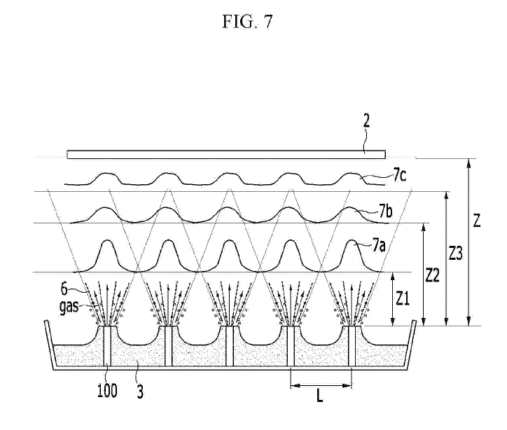

FIG. 7 shows a graph for indicating a form of a thin film provided according to a shortest distance (Z) to a substrate from a plurality of electrodes in a thin-film forming device according to an exemplary embodiment.

Referring to FIG. 7, differing from FIG. 5 and FIG. 6, when the sprayed particles 6 are sprayed by a plurality of electrodes 100, the velocity profile U(r, Z) of the sprayed particles 6 is influenced by the shortest distance (Z) to the substrate from the electrode.

In one exemplary embodiment, for example, in a first area Z1 that is greater than the threshold point, a thin film with a first form 7a with a relatively big thickness deviation corresponding to a velocity distribution caused by the electrodes 100 may be formed. However, in a second area Z2 that is further distant than the first area Z1, an area where neighboring electrodes 100 overlap each other is generated, the distance between the electrode 100 and the substrate 2 becomes distant, so a thin film with a second form 7b of which the thickness deviation is supplemented compared to the first form 7a may be formed. Further, in a third area Z3 that is further distant than the second area Z2, an area where a plurality of electrodes 100 overlap each other is generated and the distance between the electrode 100 and the substrate 2 becomes further distant compared to the above-described second area Z2 so a thin film with a third form 7c of which the deviation is further supplemented compared to the second form 7b may be formed.

When the sprayed particles 6 are sprayed by a plurality of electrodes 100 as described, the thin film of which the thickness deviation is relatively supplemented may be formed as the shortest distance (Z) to the substrate from the electrode is sufficiently obtained.

The velocity profile U(r, Z) of the sprayed particles 6 may be influenced by a distance (L) among a plurality of electrodes, that is, a distance between two adjacent electrodes, as shown in FIG. 7. When the distance (L) among a plurality of electrodes is set to be short, distribution areas of the sprayed particles 6 sprayed by a plurality of electrodes 100 overlap each other so the thin film with a uniform thickness may be formed when the shortest distance (Z) to the substrate is set to be shorter.

However, when the distance among the electrodes 100 becomes closer, the electrostatic interference substantially increases so a minimum applying voltage for spraying the sprayed particles 6 substantially increases. That is, the liquid droplets may not be effectively transformed into sprayed particles 6 between the two adjacent electrodes 100 such that the multi-spray mode condition may not be effectively maintained.

Therefore, in an exemplary embodiment, the distance L among a plurality of electrodes 100 may be greater than about 2 mm, about 5 mm, or about 10 mm, for example, to maintain the multi spray mode condition.

The velocity profile U(r, Z) of the sprayed particles 6 sprayed by one electrode 100 may satisfy Equation 1:

$$U ( r , Z ) = \frac{Uo ( Z )}{{( 2 π )}^{0.5} * σ} {e}^{\frac{- {r}^{2}}{2 {σ}^{2}}} \qquad [ Equation 1 ]$$

In Equation 1, r denotes a distance separated from the center axis in a vertical direction to the center axis shown in FIG. 5, Z denotes a shortest distance to the substrate from the electrodes, Uo(Z) denotes a center velocity, and σ denotes a standard deviation of a velocity profile.

The center velocity may satisfy Equation 2:

$$Uo ( Z ) = \frac{Zo}{Z} * Uo \qquad [ Equation 2 ]$$

In Equation 2, Zo denotes a threshold distance, and Uo denotes an initial velocity.

The standard deviation σ may satisfy Equation 3.

$$σ = \frac{Z}{Zo} * D \qquad [ Equation 3 ]$$

In Equation 3, D denotes a width of a gas spraying channel.

Equation 4 may be obtained by substituting Equation 2 and Equation 3 for Equation 1:

$$U ( r , Z ) = \frac{\frac{Uo}{D} * {( \frac{Zo}{Z} )}^{2}}{{( 2 π )}^{0.5}} {e}^{- \{ \frac{r}{D} * {( \frac{Zo}{Z} )}^{2} \}} \qquad [ Equation 4 ]$$

The threshold distance Zo represents a distance within which the spraying force of the sprayed gas effectively gives an influence, threshold distance Zo may be 8 to 10 times the width D of the gas spraying channel, and Equation 5 is obtained assuming that the distance Zo is 10 times the width D in an exemplary embodiment.

Zo=10*D [Equation 5]

Equation 5 is substituted with Equation 4 to remove D and Zo, thereby obtaining Equation 6 when shown as a relative value on the initial velocity of the velocity profile U(r, Z).

$$\frac{U ( r , Z )}{Uo} = \frac{D * {( \frac{10}{Z} )}^{2}}{{( 2 π )}^{0.5}} {e}^{- \frac{{( \frac{10 * r}{Z} )}^{2}}{2}} \qquad [ Equation 6 ]$$

The relative value on the initial velocity of the velocity profile U(r, Z) calculated from Equation 6 shows a velocity distribution of the sprayed particles 6 by one electrode 100.

However, Equation 6 assumes that one electrode is provided in the thin-film forming device. In an exemplary embodiment, where a plurality of electrodes separated from each other with a regular interval L between neighboring electrodes of Equation 6 are provided, velocity distributions for respective electrodes overlap each other, and the deviations of the velocity distributions are mutually supplemented like the shape of the second form 7b and the third form 7c as shown in FIG. 7. The velocity distributions that are mutually overlapped by a plurality of electrodes will be defined to be a total velocity distribution in an exemplary embodiment.

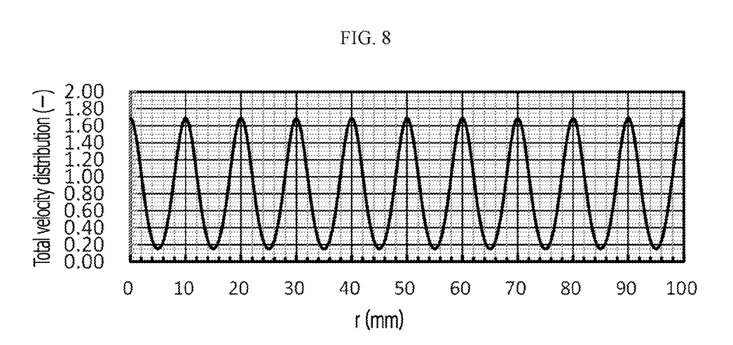

FIG. 8 shows a graph for indicating a total velocity distribution according to a distance from a center axis of gas sprayed by a gas spraying channel when L=10 mm and Z=20 mm in a thin-film forming device according to an exemplary embodiment.

In one exemplary embodiment, for example, when it is set that L=10 mm and Z=20 mm, the total velocity distribution for the distance r separated from the center axis of the gas sprayed from the gas spraying channel shows a very big deviation as shown in FIG. 8, and the deviation between the maximum value and the minimum value is about 1.4. That is, according to the condition of FIG. 8, the deviation of the total velocity distribution for r may be about 140% to the maximum, and the thickness of the resultantly formed thin film has a very big deviation with reference to the form of the graph of FIG. 8.

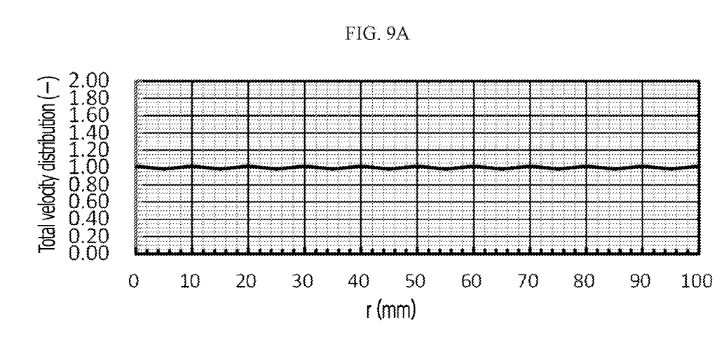

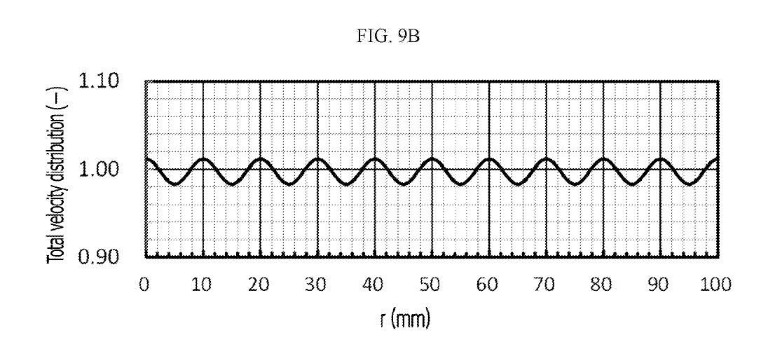

FIGS. 9A and 9B shows a graph for indicating a total velocity distribution according to a distance from a center axis of gas sprayed by a gas spraying channel in a thin-film forming device according to an exemplary embodiment, where FIG. 9A is a graph when L=10 mm and Z=50 mm and FIG. 9B is a magnified graph of FIG. 9A in a y-axis direction.

When Z is increased to be 50 mm as shown in FIG. 9A and FIG. 9B, a substantially reduced deviation is shown compared to FIG. 8. In this case, as shown in FIG. 9B, the deviation of the total velocity distribution is reduced to be about 0.03, that is, the deviation of the total velocity distribution for r is substantially reduced to be about 3% to the maximum.

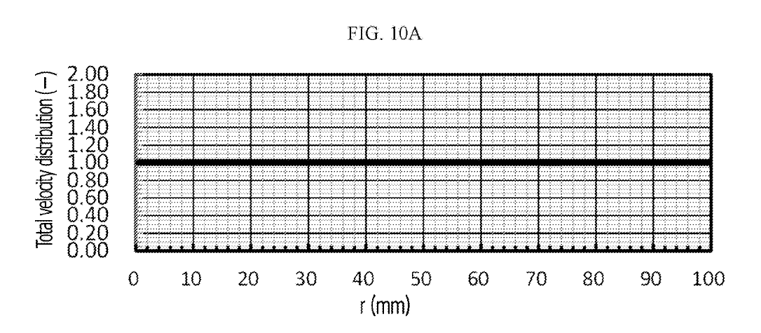

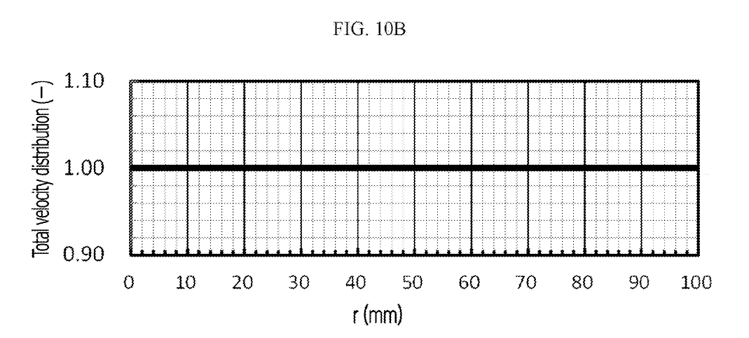

FIGS. 10A and 10B shows a graph for indicating a total velocity distribution according to a distance from a center axis of gas sprayed by a gas spraying channel in a thin-film forming device according to an exemplary embodiment where FIG. 10A is a graph when L=10 mm and Z=100 mm and FIG. 10B is a magnified graph of FIG. 10A in a y-axis direction.

When Z is increased to be 100 mm as shown in FIG. 10A, and FIG. 10B, the deviation converges to about zero (0), that is, the deviation of the total velocity distribution for r is not generated, compared to FIG. 8, FIG. 9A, and FIG. 9B.

When Z is increased to be greater than L by more than about 5 times, it is checked that the deviation of the total velocity distribution may be reduced.

When the D value is changed to 10 μm, 30 μm, and 100 μm in the condition of FIG. 8, FIG. 9A, FIG. 9B, FIG. 10A and FIG. 10B, the same results as those of FIG. 8, FIG. 9A, FIG. 9B, FIG. 10A and FIG. 10B may be obtained.

The D value influences the velocity distribution for respective electrodes as shown in 6, and in the case of the total velocity distribution where a plurality of electrodes are disposed in a like manner of an exemplary embodiment, the velocity distributions among a plurality of electrodes overlap each other and are supplemented and the D value may not give an influence.

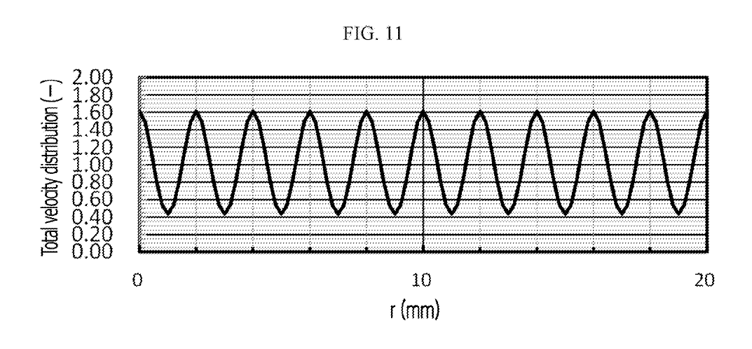

FIG. 11 shows a graph for indicating a total velocity distribution according to a distance from a center axis of gas sprayed by a gas spraying channel when L=2 mm and Z=5 mm in a thin-film forming device according to an exemplary embodiment.

In one exemplary embodiment, for example, when the gap is reduced as that L=2 mm and Z=5 mm compared to FIG. 8, the total velocity distribution value for the distance r separated from the center axis of the gas sprayed from the gas spraying channel shows a very big deviation in a like manner of FIG. 8, for example, about 1.2. That is, according to the condition of FIG. 11, the deviation of the total velocity distribution for r may be generated up to about 120%.

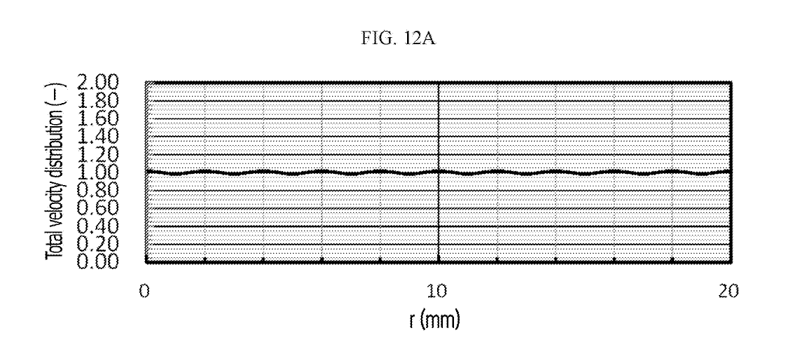

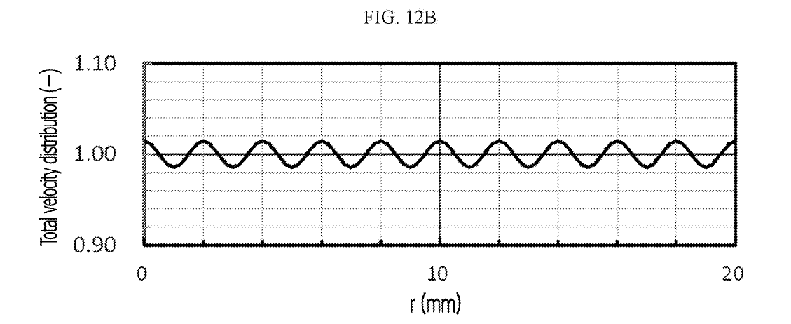

FIGS. 12A and 12B shows a graph for indicating a total velocity distribution according to a distance from a center axis of gas sprayed by a gas spraying channel in a thin-film forming device according to an exemplary embodiment where FIG. 12A is a graph when L=2 mm and Z=10 mm and FIG. 12B is a magnified graph of FIG. 12A in a y-axis direction.

When Z is increased to be 10 mm as shown in FIG. 12A and FIG. 12B, a substantially reduced deviation is shown compared to FIG. 11. In this case, as shown in FIG. 12B, the deviation of the total velocity distribution is reduced to be about 0.04, that is, the deviation of the total velocity distribution for r is substantially reduced to be about 4% to the maximum.

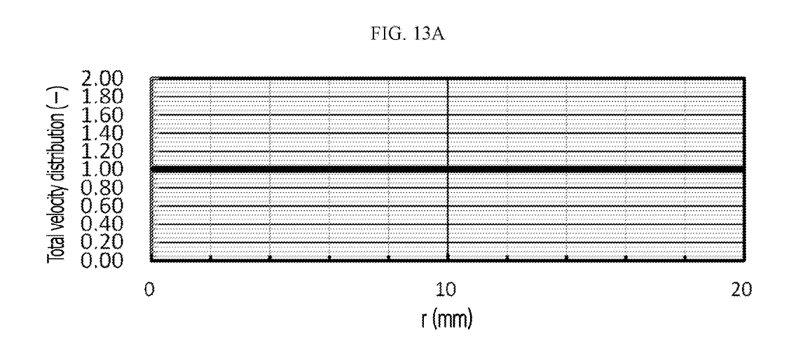

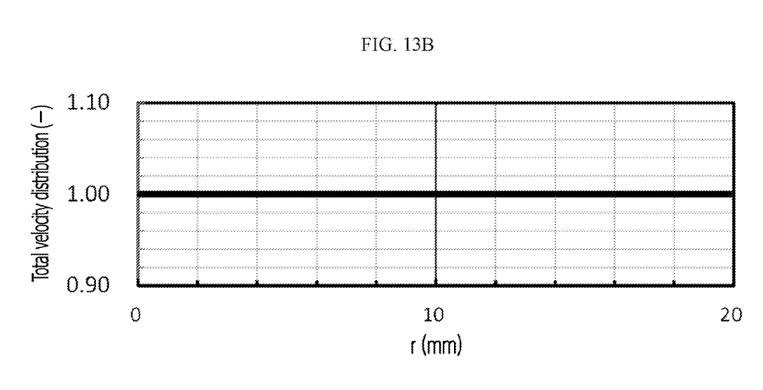

FIGS. 13A, and 13B shows a graph for indicating a total velocity distribution according to a distance from a center axis of gas sprayed by a gas spraying channel in a thin-film forming device according to an exemplary embodiment where FIG. 13A is a graph when L=2 mm and Z=15 mm and FIG. 13B is a magnified graph of FIG. 13A in a y-axis direction.

When Z is increased to be 15 mm as shown in FIG. 13A and FIG. 13B, it is checked that the deviation converges to 0 in a similar manner of FIG. 10A and FIG. 10B, that is, the deviation of the total velocity distribution for r is not generated.

When Z is increased to be greater than L by more than about 5 times, it is checked that the deviation of the total velocity distribution may be reduced.

When the D value is changed to 10 μm, 30 μm, and 100 μm in the condition of FIG. 11, FIG. 12A, FIG. 12B, FIG. 13A, and FIG. 13B, the same results as those of FIG. 11, FIG. 12A, FIG. 12B, FIG. 13A, and FIG. 13B, may be obtained, which is analyzed to be caused by the same reason as the case of FIG. 8, FIG. 9A, FIG. 9B, FIG. 10A and FIG. 10B.

As described above, the total velocity distribution formed by a plurality of electrodes become different depending on L and Z, and when Z increases, the deviation of the total velocity distribution shows a decrease. Further, when L is set to be 10 mm or 2 mm and Z is set to be greater than L by about 5 times, the deviation of the total velocity distribution may be reduced to be less than about 4%.

The thickness deviation of the formed thin film corresponds to the deviation of the total velocity distribution so the thickness deviation of the thin film may be also influenced by L and Z.

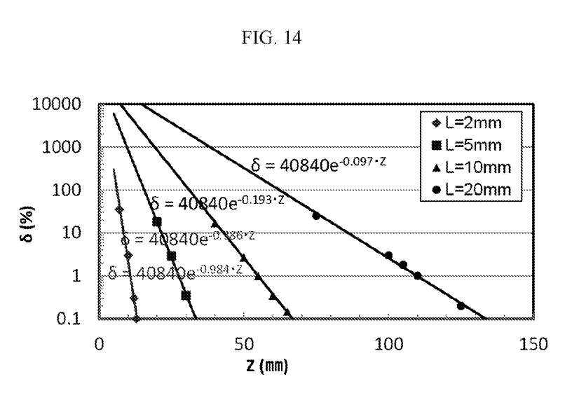

FIG. 14 shows a graph for indicating a relationship of a thickness deviation δ with respect to Z according to a change of L.

A thickness deviation δ of a thin film according to a change of Z when L is fixed to be 2 mm, 5 mm, 10 mm, and 20 mm is shown in FIG. 14. Referring to FIG. 14, when the Z value increases, the thickness deviation δ may reduce in an algebraic manner, and when the y axis is expressed with respect to a logarithmic unit, linearity is indicated.

An approximate equation of δ with respect to Z will be as follows:

δ=A*e^{-B*Z} [Equation 7]

Here, A and B are obtained from a graph of FIG. 14, A is a constant, and B is variable with L.

A and B may be expressed in Table 1.

TABLE 1

| | L = 2 mm | L = 5 mm | L = 10 mm | L = 20 mm |
|---|---|---|---|---|
| A | 40840 | 40840 | 40840 | 40840 |
| B | 0.984 | 0.386 | 0.193 | 0.097 |

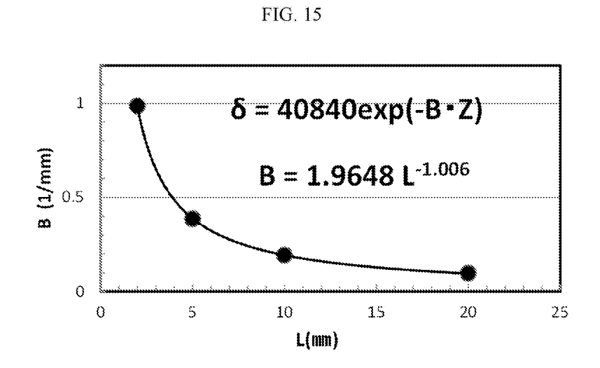

FIG. 15 shows a graph for indicating a correlation of L and B expressed in Table 1.

A relationship of L and B expressed in Table 1 is shown in FIG. 15, which may be expressed with respect to B.

B=1.9648*L^{-1.006} [Equation 8]

Here, −1.006 is approximate to −1 so Equation 8 may be given as the following approximate expression.

$$B = \frac{1.96}{L} \qquad [ Equation 9 ]$$

When Equation 9 is substituted with Equation 7 and A is further with 40840, Equation 10 for the thickness deviation δ of the thin film for Z and L may be acquired.

$$δ = 40840 * {e}^{- 1.96 * \frac{Z}{L}} \qquad [ Equation 10 ]$$

Therefore, regarding the thin-film forming device 10 according to an exemplary embodiment, the thin film with the minimized thickness deviation may be provided by controlling Z and L. In one exemplary embodiment, for example, the thickness deviation δ that is less than about 2% is desired to be maintained for the general organic light emitting diode to have high light emission characteristic, which may be achieved by controlling Z and L to satisfy the following inequation: Z≧5L or Z≧5.06L. When the thickness deviation δ is desired to be less than about 1%, it may be achieved by controlling Z and L to satisfy the following inequation: Z≧5.4L or Z≧5.42L.

Accordingly, the thin-film forming device 10 according to an exemplary embodiment may control the thickness deviation of the thin film by controlling the distance Z to the substrate from the front end of the electrode and the distance L between neighboring electrodes. In one exemplary embodiment, for example, the thin-film forming device 10 may generate the thin film with the minimized thickness deviation by controlling the distance Z to be greater than the distance L by more than 5 times.

A thin-film forming device 20 according to an alternative exemplary embodiment will now be described. When the thin-film forming device 20 is described, same configurations as the thin-film forming device 10 according to an exemplary embodiment will be omitted.

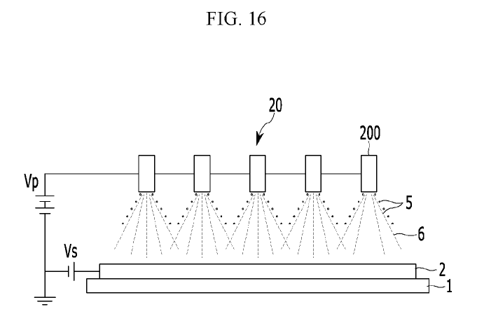

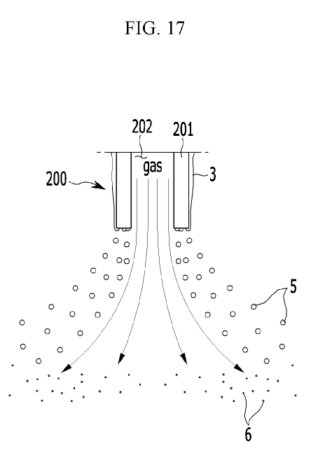

FIG. 16 shows a schematic diagram of a thin-film forming device according to an alternative exemplary embodiment and FIG. 17 shows a magnified end portion of an electrode of FIG. 16.

Referring to FIG. 16, differing from an exemplary embodiment of the thin-film forming device 10 described above with reference to FIGS. 1 to 3, in an alternative exemplary embodiment of the thin-film forming device 20, the thin-film forming material is not filled in the electrode tank, and as shown in FIG. 17, the thin-film forming material goes down from an external circumferential surface of the electrode 200.

In such an embodiment, the electrode 200 is disposed on an upper portion of the thin-film forming device 20 and the substrate 2 is disposed below the thin-film forming device 20 so the liquid droplets 5 sprayed by the thin-film forming device 20 move downward, thereby enabling a down-flow type formation of a thin film.

A thin-film forming material supplier (not shown) for carrying the thin-film forming material may be provided near the electrode 200 so that the thin-film forming material may be attached to the external circumferential surface of the electrode 200 and may go down. The thin-film forming material supplier (not shown) may control the external circumferential surface of the electrode 200 to be wet with the thin-film forming material 3 by using a method for periodically spraying the thin-film forming material 3 toward the external circumferential surface of the electrode 200.

The thin-film forming material 3 having gone down from the external circumferential surface of the electrode 200 is gathered on the cross-section of the electrode 200 and is then sprayed in the shape of liquid droplets 5. The sprayed shape includes sprays generated when a predetermined voltage (Vp) is applied to the electrode 200, and sprays generated when the thin-film forming material 3 gathered at the cross-section of the electrode 200 free-falls because of the acceleration of gravity.

In such an embodiment, the sprayed gas is sprayed to the liquid droplets 5 that are sprayed to fall so the sprayed gas may efficiently vaporize and remove the moisture or solvent remaining in the liquid droplets 5.

In a conventional down flow type thin film formation process, part of liquid droplets free-falling because of the acceleration of gravity are not sufficiently influenced by the corona discharge at the front end of the electrode 200, and have much moisture or solvents that remain differing from the other liquid droplets that are sprayed by the corona discharge. Accordingly, quality of the formed thin film may be deteriorated, and the surface of the thin film may be generated to be non-uniform.

In an exemplary embodiment, the thin-film forming device 20 vaporizes and removes the moisture or solvents remaining in free-falling part of the liquid droplets so when the down flow type thin film forming process is used, the thin film with improved quality similarly to the up flow type thin film formation process described with reference to FIGS. 1 to 3 may be provided.

According to an alternative exemplary embodiment, the thin-film forming device 20 for uniformly and stably forming a quality-improved thin film when the down flow type thin film formation is used may be provided.

Efficiency and a possibility of mass production of the thin-film forming device 10 according to an exemplary embodiment will now be described in detail with reference to the following experimental examples of spraying performance.

### Experimental Example 1

A single pipe type electrode made of a stainless steel material with an interior diameter of 330 μm and an exterior diameter of 630 μm is installed in a center of a Teflon (Teflon®) container with a diameter of 100 mm and a thickness of 30 mm. A lower portion of the pipe electrode is installed to pass through the Teflon container, and an upper end of the pipe electrode is protruded to an upper side of the Teflon container. A lower end of the pipe electrode is connected to a gas supply device.

A metal plate of a stainless steel material is disposed on a position that is distant from the pipe electrode by 35 mm. The metal plate is grounded with an earth voltage, e.g., zero volt (0 V), and a surface facing the pipe electrode is applied with a permanent pen.

Isopropyl alcohol (“IPA”) is filled in the Teflon container, and a flow is controlled so that the protruded front end of the pipe electrode may be protruded over an interface of the IPA by 1 mm. A voltage of 20 kV is applied as a positive potential to the pipe electrode. Simultaneously, air is supplied from the connected gas supply device, the air is sprayed through an upper end of the pipe electrode for one minute with a pressure of 80 psi, and the sprayed state of the IPA sprayed from the front end of the pipe electrode is observed with eyes.

When the spraying is finished, “Total spraying amount of IPA=cross-section of Teflon container×(IPA flow height when spraying started−IPA flow height when spraying finished) % total spraying time” is calculated, and a result is expressed in Table 2.

When the spraying is finished, the substrate with remainders of traces of IPA liquid droplets is separated and is then observed through an optical microscopic, so the size of the sprayed IPA liquid droplets is measured and the result is expressed in Table 2.

### Experimental Example 2

Except the point that the pressure of the nitrogen gas sprayed from the pipe electrode is reduced to 40 pounds per square inch (psi), the experiment is performed in the same condition as Experimental Example 1, the spraying state is observed with eyes, and when the spraying is finished, the total sprayed amount of the IPA and the size of the sprayed IPA liquid droplets are measured, and the results are expressed in Table 2.

### Experimental Example 3

Except the point that the voltage applied to the pipe electrode is increased to 23 kV, the experiment is performed in the same condition as Experimental Example 1, the spraying state is observed with eyes, and when the spraying is finished, the total sprayed amount of the IPA and the size of the sprayed IPA liquid droplets are measured, and the results are expressed in Table 2.

### Comparative Example 1

A syringe pump is connected to the single pipe type electrode made of a stainless steel material with an interior diameter of 200 μm and an exterior diameter of 400 μm. The same IPA as Experimental Example 1 is charged to the syringe pump. The pipe electrode is disposed to spray the IPA downward, and a substrate below the pipe electrode, the same metal plate as Experimental Example 1 is disposed at a position that is distant from the pipe electrode by 70 mm.

When a constant pressure is applied to the syringe pump and the voltage of 8.7 kV is simultaneously applied as a positive potential to the pipe electrode, the IPA flows from the syringe pump with a constant fluid pressure by a constant pressure, and the IPA is electro-sprayed by the applied voltage. The electro-spraying state is observed with eyes, and when the spraying is finished, the IPA reduced amount inside syringe pump is calculated to produce the total sprayed amount of IPA, and when the spraying is finished, the substrate with remainders of traces of IPA liquid droplets is separated and is then observed through an optical microscopic, so the size of the sprayed IPA liquid droplets is measured and the result is expressed in Table 2.

### Comparative Example 2

A second pipe structure made of a stainless steel material with an interior diameter of 200 μm and an exterior diameter of 400 μm is inserted into a first pipe structure made of a stainless steel material with an interior diameter of 330 μm and an exterior diameter of 630 μm, which configures a double-pipe shaped pipe electrode, and the syringe pump of Comparative Example 1 is connected to the first pipe structure, and the gas supply device of Experimental Example 1 is connected between the first pipe structure and the second pipe structure.

The pipe electrode is disposed to spray the IPA downward, and a substrate below the pipe electrode, the same metal plate as Experimental Example 1 is disposed at a position that is distant from the pipe electrode by 70 mm.

When a constant pressure is applied to the syringe pump and the voltage of 9.4 kV is simultaneously applied as a positive potential to the pipe electrode, the IPA flows from the syringe pump with a constant fluid pressure by a constant pressure, and the IPA is electro-sprayed by the applied voltage. Simultaneously, air is sprayed with the pressure of 40 psi for one minute from between the first pipe structure and the second pipe structure.

The electro-spraying state is observed with eyes, and when the spraying is finished, the IPA reduced amount inside syringe pump is calculated to produce the total sprayed amount of IPA, and when the spraying is finished, the substrate with remainders of traces of IPA liquid droplets is separated and is then observed through an optical microscopic, so the size of the sprayed IPA liquid droplets is measured and the result is expressed in Table 2.

### Comparative Example 3

Except the point that the protruded front end of the pipe electrode is disposed to be lower than the interface of the IPA by 1 mm, the flow is controlled so that the pipe electrode may be soaked in the IPA, and the air is sprayed with the pressure of 80 psi for one minute while no voltage is applied to the pipe electrode, the spraying state is observed with eyes, and when the spraying is finished, the total sprayed amount of the IPA and the size of the sprayed IPA liquid droplets are measured, and the results are expressed in Table 2.

TABLE 2

| | Exemplary | Exemplary | Exemplary | Comparative | Comparative | Comparative |
|---|---|---|---|---|---|---|
| | embodiment 1 | embodiment 2 | embodiment 3 | Example 1 | Example 2 | Example 3 |
| Z | 35 mm | 35 mm | 35 mm | 70 mm | 70 mm | 35 mm |
| Applied | 20 kV | 20 kV | 23 kV | 8.7 kV | 9.4 kV | 0 kV |
| voltage | | | | | | |
| Sprayed gas | 80 psi | 40 psi | 80 psi | — | 40 psi | 80 psi |
| pressure | | | | | | |
| Sprayed | 1000 μL/min | 300 μL/min | 2000 μL/min | 30 μL/min | 50 μL/min | 5000 μL/min |
| amount | | | | | | |
| Size of | Less than 100 μm | Less than 100 μm | Less than 100 μm | Less than 100 μm | Less than 100 μm | Less than 500 μm |
| sprayed liquid | | | | | | |
| droplets | | | | | | |

In the case of Experimental Example 1, it is observed that the IPA surrounding the pipe electrode goes up along the surface of the pipe electrode, and the liquid droplets are gathered on the circular cross-section of the pipe electrode and are sprayed in the multi spray mode. Further, very fine particles form cloud and mist between the pipe electrode and the substrate, the cloud and mist are considered to be a gathering of sprayed liquid droplets, and the cloud and mist are observed to quickly move by sprayed gas.

Referring to Table 2, it is found in the case of Experimental Example 1 that the size of the actually sprayed liquid droplets is very fine, that is, less than 100 μm, and the sprayed amount is 1,000 microliter per minute (μL/min), which is very big compared to Comparative Example 1 or Comparative Example 2, which is because the liquid droplets are quickly sprayed by the sprayed gas.

In the case of Experimental Example 2, in a like manner of Experimental Example 1, it is observed that the liquid droplets are gathered on the circular cross-section of the pipe electrode and are sprayed in the multi spray mode, and it is checked that the cloud and mist move relatively slowly than Experimental Example 1. This is because the pressure of the sprayed gas is reduced compared to Experimental Example 1.

Referring to Table 2, it is found in the case of Experimental Example 2 that the size of the actually sprayed liquid droplets is very fine, that is, less than 100 μm, and the sprayed amount is 300 μL/min, which is very big compared to Comparative Example 1 or Comparative Example 2, which is because the liquid droplets are quickly sprayed by the sprayed gas.

In the case of Experimental Example 3, in a like manner of Experimental Example 1, it is observed that the liquid droplets are gathered on the circular cross-section of the pipe electrode and are sprayed in the multi spray mode, and it is checked that the thicker cloud and mist than those of Experimental Example 1 are generated. This is because a stronger voltage than that of Experimental Example 1 is applied to the pipe electrode and the amount of IPA sprayed at the front end of the pipe electrode is increased.

Referring to Table 2, it is found in the case of Experimental Example 3 that the size of the actually sprayed liquid droplets is very fine, that is, less than 100 μm, and the sprayed amount is 2,000 μL/min, which is very much big compared to Comparative Example 1 or Comparative Example 2, which is because the liquid droplets are quickly sprayed by the sprayed gas.

In the case of Comparative Example 1, the liquid droplets are sprayed on the surface of the pipe electrode in the multi spray mode, and it is checked that there are not many liquid droplets that are gathered on the circular cross-section of the pipe electrode compared to Experimental Examples 1 to 3. Further, it is observed that the cloud and mist are formed between the electrode and the substrate and they move relatively slowly. This is because, compared to Experimental Examples 1 to 3, there is no means to move the cloud and mist toward the substrate such as sprayed gas.

Referring to Table 2, the size of the sprayed liquid droplets is less than 100 μm that is very fine, and the sprayed amount is 30 μL/min that is very less so it seems difficult to apply the above-described structure to mass production.

In the case of Comparative Example 2, it is observed that the liquid droplets are sprayed in the multi spray mode on the surface of the first pipe structure, and in a like manner of Comparative Example 1, there are not many liquid droplets that are gathered on the circular cross-section of the pipe electrode. It is observed, compared to Comparative Example 1, that the cloud and mist between the electrode and the substrate move faster, which is because the sprayed gas accelerate the moving of cloud and mist toward the substrate.

Referring to Table 2, the size of the sprayed liquid droplets is less than 100 μm that is very fine, and the sprayed amount is 50 μL/min, which is very less compared to Experimental Examples 1 to 3, so it seems difficult to apply the above-described structure to mass production.

In the case of Comparative Example 3, it is observed that the liquid droplets are scattered to be sprayed by the sprayed gas on the surface of the pipe electrode, and differing from Experimental Examples 1 to 3, the size of the sprayed particles is not uniform. Particularly, in the case of Comparative Example 3, the liquid droplets are coarse-sized, and intermittently sprayed between the electrode and the substrate, and the cloud and mist like Experimental Examples 1 to 3 are not generated. This is because the IPA is sprayed with the sprayed gas while not applying a voltage to the pipe electrode.

Referring to Table 2, the size of the sprayed liquid droplets is less than 500 μm, a deviation of the liquid droplets observed with eyes is big so it seems difficult to apply the above-described structure to the thin film forming process even though the sprayed amount is 5,000 μL/min that is very high, compared to Experimental Examples 1 to 3.

In summary, in the case of Experimental Examples 1 to 3, the size of the sprayed liquid droplets is less than 100 μm that is very fine, so when they are exemplarily applied to the formation of an organic thin film used for the organic thin film displaying diode, the thin film with an excellent displaying characteristic may be manufactured. That is, the thin-film forming device 10 according to an exemplary embodiment may form a high precision and high quality thin film.

In addition, Experimental Examples 1 to 3 have the sprayed amount that is greater than 300 μL/min, which is a very big value, so it is advantageous in mass production of the thin films. Accordingly, as described above, the thin-film forming device 10 according to an exemplary embodiment has a sufficient sprayed amount while having a relatively simple electrode structure with a single pipe shape, which is effectively applicable to mass production of the thin films using the ESD.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin-film forming device comprising:
a plurality of electrodes for spraying a thin-film forming material; and
a substrate stand disposed to face the plurality of pipe electrodes and which holds a substrate for forming a thin film thereon,
wherein a gas spraying channel for spraying gas for drying the sprayed thin-film forming material is defined in each of the electrodes, and
when a gap between neighboring electrodes is denoted by L and a shortest distance from the electrodes to the substrate held on the substrate stand is denoted by Z, L and Z satisfy the following inequation: Z≧5L.

2. The thin-film forming device of claim 1, wherein
L has a value in a range of about 5 mm to about 20 mm.

3. The thin-film forming device of claim 1, wherein
Z has a value equal to or greater than about 30 mm.

4. The thin-film forming device of claim 1, wherein
when a thickness deviation of the formed thin film is denoted by δ (%), δ satisfies the following equation: δ=40840*e^{-1.96*Z/L}.

5. The thin-film forming device of claim 4, wherein
Z and L satisfy the following inequation: Z≧5.06L.

6. The thin-film forming device of claim 1, wherein
the gas spraying channel sprays a gas comprising at least one selected from nitrogen (N₂), argon (Ar), helium (He), neon (Ne), xenon (Xe), and krypton (Kr).

7. The thin-film forming device of claim 1, wherein
the gas spraying channel extends along a center axis of the electrode.

8. The thin-film forming device of claim 7, wherein
the electrode is in a pipe shape, and
a transverse cross-section of the gas channel has a circular shape.

9. The thin-film forming device of claim 1, wherein
a front end of the electrode has a cylindrical shape, and
a transverse cross-section of the gas channel has a circular shape.

10. The thin-film forming device of claim 1, further comprising:
a plated layer disposed on a surface of the electrode.

11. The thin-film forming device of claim 10, wherein
the plated layer comprises at least one selected from a stainless steel, tungsten, gold, and platinum.

12. The thin-film forming device of claim 1, further comprising:
an electrode tank which contains the thin-film forming material,
wherein at least part of the electrode is disposed in the electrode tank.

13. The thin-film forming device of claim 12, wherein
when the thin-film forming material is contained in the electrode tank, the electrode is higher than the thin-film forming material by about 0.15 mm to about 4 mm.

14. The thin-film forming device of claim 1, wherein
the substrate stand is disposed below the electrodes.

15. A method of manufacturing an organic light-emitting diode, the method comprising forming an organic layer using the thin-film forming device of claim 1.
